(19) United States
(12) Patent Application Publication
(10) Pub. No.: US 2025/0270702 A1
(43) Pub. Date: Aug. 28, 2025

(54) WAFER SUPPORT DEVICE AND SiC EPITAXIAL GROWTH APPARATUS

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tsutomu KIYOSAWA, Himeji (JP); Masaharu SHIMABAYASHI, Ibo (JP)

(73) Assignees: KABUSHIKI KAISHA TOSHIBA, Tokyo (JP); OSHIBA ELECTRONIC DEVICES & STORAGE CORPORATION, Tokyo (JP)

(21) Appl. No.: 19/056,847

(22) Filed: Feb. 19, 2025

(30) Foreign Application Priority Data
Aug. 28, 2024 (JP) 2024-146873

(51) Int. Cl. C23C 16/458; C23C 16/32

(52) U.S. Cl. CPC C23C 16/4585; C23C 16/325; C23C 16/4584

(57) ABSTRACT

A wafer support device of an embodiment includes a support base and a wafer guide portion. The support base has a support surface supporting a wafer. The support base rotates with a central axis extending in a normal direction of the support surface as a center. The wafer guide portion includes a first chamfered portion and a second chamfered portion. The wafer guide portion has an annular shape surrounding a circumference of the wafer supported on the support surface with the central axis as a center. The first chamfered portion is inclined downward going radially inward from an upper surface with the central axis as a center. The second chamfered portion has a first inclined region facing downward at an inclination angle larger than an inclination angle of the first chamfered portion with respect to the support surface going radially inward.

### CROSS-REFERENCE TO RELATED APPLICATION

Priority is claimed on Japanese Patent Application No. 2024-146873, filed Aug. 28, 2024, the content of which is incorporated herein by reference.

### FIELD

Embodiments of the present invention relate to a wafer support device and an SiC epitaxial growth apparatus.

### BACKGROUND

In a wafer support device in an SiC epitaxial growth apparatus, for positioning and holding a wafer, a wafer guide is disposed around the wafer supported on a support surface. An inner diameter of the wafer guide is designed to be several millimeters larger than a diameter of the wafer, taking into consideration an alignment accuracy of automatic wafer transfer. In this case, when the wafer shifts to one side during an SiC epitaxial growth processing, an in-plane distribution of a thickness and carrier concentration of a resulting SiC epitaxial film may not be uniform.

On the other hand, if an inner diameter of the wafer guide is made small, a misalignment during automatic wafer transfer may cause the wafer to ride onto the wafer guide, thereby causing a problem such as wafer dropping.

Further, reaction products due to the SiC epitaxial growth processing are accumulated on the wafer guide. In order to perform the SiC epitaxial growth processing smoothly, regeneration of the wafer guide is performed by removing accumulated reaction products through a polishing processing or the like. If a portion of the wafer guide in which an upper surface and a circumferential surface intersect, where reaction products are likely to accumulate, is subjected to a removal processing, damage may occur.

### BRIEF DESCRIPTION OF THE DRAWINGS

FIG. 1 is a cross-sectional view illustrating an SiC epitaxial growth apparatus of an embodiment.

FIG. 2 is a cross-sectional view illustrating a wafer support device of a first embodiment.

FIG. 3 is a partial enlarged view of FIG. 2.

FIG. 4 is a cross-sectional view in which a lift unit is at a raised position.

FIG. 5 is a partial enlarged view illustrating the wafer support device when a misalignment has occurred.

FIG. 6 is a partial enlarged view illustrating the wafer support device when a misalignment has occurred.

FIG. 7 is a partial cross-sectional view illustrating the wafer support device after an SiC epitaxial growth processing.

FIG. 8 is a partial cross-sectional view illustrating the wafer support device after an SiC epitaxial growth processing.

FIG. 9 is a partial enlarged view illustrating a wafer support device of a second embodiment.

FIG. 10 is a partial enlarged view illustrating a wafer support device of a third embodiment.

FIG. 11 is a partial enlarged view illustrating a wafer support device of a fourth embodiment.

### DETAILED DESCRIPTION

A wafer support device of an embodiment includes a support base and a wafer guide portion. The support base has a support surface supporting a wafer. The support base rotates around a central axis extending in a normal direction of the support surface. The wafer guide portion includes a first chamfered portion and a second chamfered portion. The wafer guide portion has an annular shape that surrounds a circumference of the wafer supported on the support surface with the central axis as a center. The first chamfered portion is inclined downward going radially inward from an upper surface of the wafer guide portion with the central axis as a center. The second chamfered portion has a first inclined region that inclines downward at an inclination angle larger than an inclination angle of the first chamfered portion with respect to the support surface going radially inward. The second chamfered portion is connected to an inner side of the first chamfered portion in the radial direction.

Hereinafter, a wafer support device and an SiC epitaxial growth apparatus of embodiments will be described with reference to the drawings. In the following description, components having the same or similar functions will be denoted by the same reference signs. Also, duplicate description of the components may be omitted.

Hereinafter, a configuration of an SiC epitaxial growth apparatus will be described.

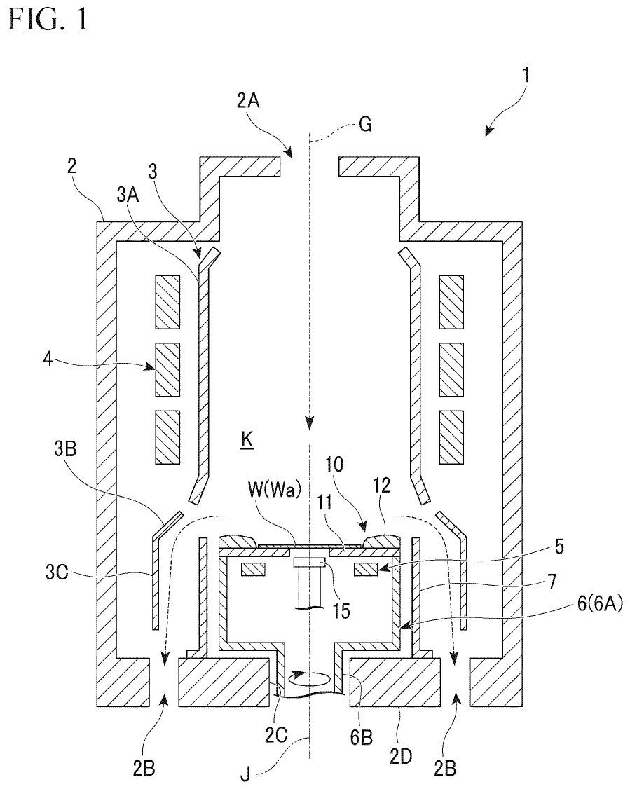

FIG. 1 is a cross-sectional view of an SiC epitaxial growth apparatus 1 having a wafer support device 10 of an embodiment.

In the following description, a side into which a supplied source gas flows is referred to as an upper side, and a side from which the source gas flows out is referred to as a lower side. In the following description, a direction along a central axis J will be simply referred to as an “axial direction”. Also, a radial direction with the central axis J as a center may be simply referred to as a “radial direction”. Regarding the “radial direction,” a side approaching the central axis J is referred to as an inner side, and a side away from the central axis J is referred to as an outer side. Further, a circumferential direction around the central axis J may be simply referred to as a “circumferential direction”.

As illustrated in FIG. 1, the SiC epitaxial growth apparatus 1 grows an epitaxial film, which serves as an active region, on a wafer W formed of silicon carbide (SiC) using chemical vapor deposition (thermal CVD) or the like. The SiC epitaxial growth apparatus 1 includes a chamber 2, a reactor 3, an upper heater 4, a lower heater 5, a partition cylinder 7, and the wafer support device 10.

The chamber 2 is formed of a metal material such as stainless steel (SUS). The chamber 2 houses the reactor 3, the upper heater 4, the lower heater 5, a rotating cylinder 6, the partition cylinder 7, and the wafer support device 10 therein. The chamber 2 has an introduction port 2A, an exhaust port 2B, and an insertion port 2C. The introduction port 2A is provided at an upper part of the chamber 2. The exhaust port 2B and the insertion port 2C are provided to penetrate a bottom wall 2D of the chamber 2 in the axial direction.

The introduction port 2A is formed to open at an upper end of the chamber 2. The introduction port 2A is a portion through which a gas to be used containing a source gas G, which is supplied from above along the central axis J, is introduced into the chamber 2. The exhaust port 2B is a portion through which a used gas including the source gas G, which has been utilized in a SiC epitaxial growth processing, is exhausted.

The source gas G reacts on the wafer W to form an epitaxial film. The source gas G is, for example, a Si-based gas and a C-based gas. The Si-based gas includes, for example, silane (SiH₄), dichlorosilane (SiH₂Cl₂), trichlorosilane (SiHCl₃), and tetrachlorosilane (SiCl₄). The C-based gas is, for example, propane (C₃H₈). As an example, the source gas G of the embodiment is SiH₄+C₃H₈ (flow rate: several tens to several hundred sccm).

Other gases used in addition to the source gas G include an impurity gas, a carrier gas, and other gases. Examples of the impurity gas include N₂ (N-type impurity) and TMA (P-type impurity). A flow rate of the impurity gas is preferably in a range of several [sccm] to several hundred [sccm]. Examples of the carrier gas include H₂ (during growth) and Ar (during transfer). A flow rate of the carrier gas is preferably in a range of 100 [slm] to 200 [slm]. Other gases include HCl (for particle suppression during growth and for a high growth rate). A flow rate of the HCl gas is preferably in a range of several tens [sccm] to several [slm].

The reactor 3 constitutes a furnace. As an example, the reactor 3 is formed of graphite. An inner surface of the reactor 3 may have an SiC coating or a TaC coating to prevent particle generation. The reactor 3 has a first cylindrical portion 3A, a tapered portion 3B, and a second cylindrical portion 3C.

The first cylindrical portion 3A is positioned on an upper side of the reactor 3. The first cylindrical portion 3A has a cylindrical shape with the central axis J as a center. The first cylindrical portion 3A opens on a lower side of the introduction port 2A in the chamber 2. A gas containing the source gas G introduced from the introduction port 2A is introduced into an internal space of the reactor 3. The internal space of the reactor 3 is a film formation space K.

The tapered portion 3B extends downward in a radially outward direction from a lower end of the first cylindrical portion 3A. The second cylindrical portion 3C has a cylindrical shape with the central axis J as a center. The second cylindrical portion 3C extends downward from a lower end of the tapered portion 3B. A radial position of the second cylindrical portion 3C is radially outward from the exhaust port 2B of the chamber 2. The tapered portion 3B is disposed in a range including an axial position of a first surface Wa of the wafer W facing upward in a vertical direction. That is, the tapered portion 3B is disposed in a range including a position intersecting a virtual plane that includes the first surface Wa of the wafer W. Therefore, the gas containing the source gas G introduced from the introduction port 2A into the film formation space K flows radially outward along the first surface Wa after reaching the wafer W. The gas containing source gas G that has flowed radially outward from the wafer W is guided by the tapered portion 3B and the second cylindrical portion 3C and is exhausted from the exhaust port 2B of the chamber 2.

The upper heater 4 surrounds an outer circumference of the first cylindrical portion 3A of the reactor 3 in the circumferential direction. The upper heater 4 extends in the axial direction along the first cylindrical portion 3A. The lower heater 5 is disposed below the wafer support device 10 to be spaced apart from the wafer support device 10. As an example, the lower heater 5 has an annular shape extending in the circumferential direction. The wafer W is heated to a range of, for example, 1500 to 1650° C. by the upper heater 4 and lower heater 5. The upper heater 4 and the lower heater 5 may utilize known heaters.

The partition cylinder 7 is fixed to the bottom wall 2D of the chamber 2. The partition cylinder 7 has a cylindrical shape with the central axis J as a center. The partition cylinder 7 extends upward in the axial direction. The partition cylinder 7 is disposed radially inward of the second cylindrical portion 3C to be spaced apart radially outward from a first rotating cylinder 6A.

Hereinafter, a configuration of the wafer support device 10 will be described.

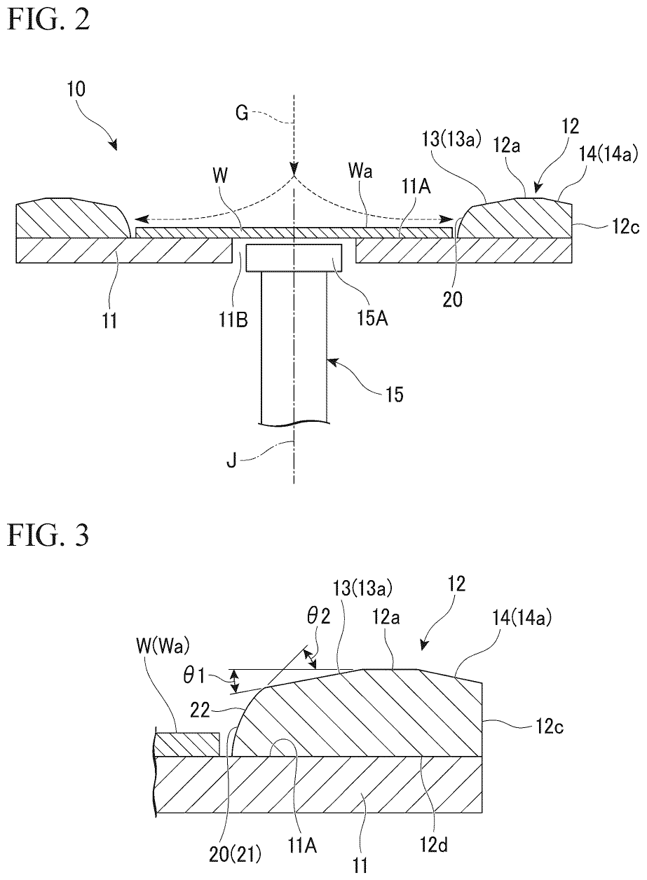

FIG. 2 is a cross-sectional view illustrating the wafer support device 10 according to the embodiment. FIG. 3 is a partially enlarged view of FIG. 2.

As illustrated in FIGS. 2 and 3, the wafer support device 10 includes the rotating cylinder 6, a support base 11, a wafer guide portion 12, and a lift unit 15.

The rotating cylinder 6 is rotatable in the circumferential direction. The rotating cylinder 6 has the cylindrical first rotating cylinder 6A centered on the central axis J, and a cylindrical second rotating cylinder 6B centered on the central axis J. The first rotating cylinder 6A is provided above the second rotating cylinder 6B. The first rotating cylinder 6A is disposed above the bottom wall 2D of the chamber 2. The lower heater 5 is disposed inside the first rotating cylinder 6A. A diameter of the first rotating cylinder 6A is larger than a diameter of the second rotating cylinder 6B. The second rotating cylinder 6B extends downward from the first rotating cylinder 6A. The second rotating cylinder 6B is inserted into the insertion port 2C.

The support base 11 has a disc shape with the central axis J as a center. The support base 11 is fixed to the first rotating cylinder 6A of the rotating cylinder 6. The support base 11 rotates in the circumferential direction due to rotation of the rotating cylinder 6. The support base 11 is a susceptor. The support base 11 has a support surface 11A and a through hole 11B. The support surface 11A supports the wafer W from below on a radially outer side of the through hole 11B. The through hole 11B penetrates the support base 11 in the axial direction with the central axis J as a center.

As an example, the support base 11 is formed of graphite. The support base 11 may have an SiC coating or a TaC coating to prevent particle generation.

### [First Embodiment of Wafer Guide Portion 12]

The wafer guide portion 12 is disposed to be joined to a circumferential edge part of the support base 11 from above. Although not illustrated in the drawings, a protruding portion protruding from one of the support base 11 and the wafer guide portion 12 to the other is provided at a joint portion between the support base 11 and the wafer guide portion 12. A recessed portion into which the protruding portion fits is provided at the other of the support base 11 and the wafer guide portion 12. The wafer guide portion 12 is fixed in the radial direction to the support base 11 by the fitting of the protruding portion and the recessed portion at the joint portion.

The wafer guide portion 12 has an annular shape that surrounds a circumference of the wafer W supported on the support surface 11A with the central axis J extending in a normal direction of the support surface 11A as a center. As an example, at least a surface of the wafer guide portion 12 is formed of poly-SiC. The wafer guide portion 12 may be configured to be formed of poly-SiC in its entirety, or may be configured to be formed of graphite with an SiC coating on a surface thereof. Also, the entirety or a part thereof may be formed of sintered SiC or single crystal SiC.

However, since there is a possibility that the wafer W may move due to a centrifugal force and collide with the wafer guide portion 12 when the wafer W rotates via the support base 11 during the epitaxial growth processing, causing the SiC coating to peel off, and therefore the wafer guide portion 12 is unsuitable for regeneration through a polishing processing to be described later, it is preferable that the wafer guide portion 12 be configured so that the entirety is formed of poly-SiC.

As illustrated in FIG. 3, in a cross section including the central axis J, the wafer guide portion 12 has a substantially rectangular outline shape surrounded by an upper surface 12a, an outer circumferential surface 12c, a lower surface 12d, a first chamfered portion 13, a second chamfered portion 20, and an outer chamfered portion 14. The outer circumferential surface 12c is a surface that faces radially outward on an outer circumferential side wall of the wafer guide portion 12. As an example, the outer circumferential surface 12c is coplanar with the outer circumferential surface of the support base 11, but it does not necessarily have to be coplanar.

In the following, the upper surface 12a, the outer circumferential surface 12c, the lower surface 12d, the first chamfered portion 13, the second chamfered portion 20, and the outer chamfered portion 14 will be described based on a cross section including the central axis J unless otherwise specified.

The first chamfered portion 13 is inclined in a direction toward a lower side as it approaches inward in the radial direction from the upper surface 12a. The first chamfered portion 13 has a first inclined surface 13a that is linearly inclined in a direction toward a lower side as it approaches inward in the radial direction. The first inclined surface 13a is inclined at an inclination angle θ1 with respect to the support surface 11A.

The outer chamfered portion 14 is inclined in a direction toward a lower side as it approaches outward in the radial direction from the upper surface 12a. The outer chamfered portion 14 has an inclined surface 14a that is linearly inclined in a direction toward a lower side as it approaches outward in the radial direction. The inclined surface 14a is inclined at the inclination angle θ1 with respect to the support surface 11A similarly to the first inclined surface 13a. The inclined surface 14a may be inclined at an inclination angle different from that of the first inclined surface 13a.

The second chamfered portion 20 has a first inclined region 21. The first inclined region 21 is inclined in a direction toward a lower side as it approaches inward in the radial direction. An upper end part of the first inclined region 21 is connected to a radially inner side of the first inclined surface 13a. The upper end part of the first inclined region 21 is positioned above the first surface Wa of the wafer W. A lower end part of the first inclined region 21 has a circular shape with the central axis J as a center and is formed to have a diameter larger than a diameter of the wafer W.

### Peel

If a position of the upper end part of the first inclined region 21 is the same as or lower than a position of the first surface Wa, the wafer W may warp due to a high temperature, causing an end edge of the wafer W to lift. In this case, when the wafer W rotates via the support base 11 during the epitaxial growth processing, the wafer W may move due to the centrifugal force and protrude beyond the wafer guide portion 12.

Therefore, when the upper end part of the first inclined region 21 is positioned above the position of the first surface Wa, protrusion of the wafer W from the wafer guide portion 12 can be suppressed.

The first inclined region 21 has a curved surface 22 that is inclined in a curved manner in a direction toward a lower side as it approaches inward in the radial direction. The curved surface 22 has an arcuate shape. The first inclined region 21 is inclined at an inclination angle θ2 with respect to the support surface 11A. The first inclined region 21 intersects the lower surface 12d of the wafer guide portion 12 at an inner end part in the radial direction. The inclination angle θ2 of the first inclined region 21 is defined as an angle of intersection of a tangent line, which is tangent to the curved surface 22, with respect to the support surface 11A. Therefore, the inclination angle θ2 increases toward the inside in the radial direction. The inclination angle θ2 is larger than the inclination angle θ1 of the first inclined surface 13a of the first chamfered portion 13.

The lift unit 15 can be raised and lowered in the axial direction. The lift unit 15 has a shaft-like shape extending in the axial direction with the central axis J as a center. The lift unit 15 has a cylindrical holding portion 15A at an upper end thereof. The holding portion 15A may be the same part as the lift unit 15, or may be a separate part connected to the lift unit 15. A diameter of the holding portion 15A is smaller than a diameter of the through hole 11B in the support base 11.

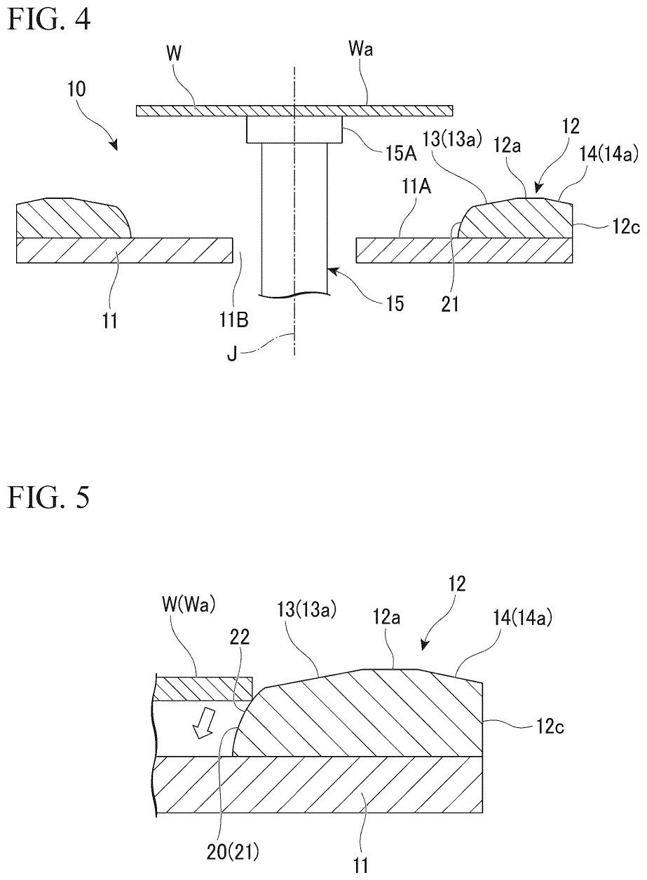

The lift unit 15 can be raised and lowered in the axial direction between a lowered position illustrated in FIG. 2 and a raised position illustrated in FIG. 4. When the lift unit 15 is at the lowered position, it is disposed below the support base 11. That is, the lowered position of the lift unit 15 refers to a position at which the holding portion 15A is below the support base 11 and is a position at which the holding portion 15A waits below the support base 11 after the wafer W is placed on the support base 11. The holding portion 15A is separated from the wafer W when the lift unit 15 is at the lowered position, but may be in contact with the wafer W when the wafer W is not rotating.

The raised position of the lift unit 15 refers to a position at which the holding portion 15A is above the wafer guide portion 12. The raised position is a position at which the wafer W, which has been removed from the support base 11 after the SiC epitaxial growth processing, is transferred to a transfer arm or the like. Also, the raised position is a position at which the wafer W before the SiC epitaxial growth processing is transferred from a transfer arm or the like.

In the SiC epitaxial growth apparatus 1 configured as described above, when the wafer W after the SiC epitaxial growth processing is removed from the wafer support device 10, the lift unit 15 rises from the lowered position at which it has been waiting and moves to the raised position while holding a lower surface of the wafer W with the holding portion 15A. The wafer W held by the holding portion 15A at the raised position is transferred to the transfer arm or the like. In the SiC epitaxial growth apparatus 1, the wafer W before the SiC epitaxial growth processing is transferred to the holding portion 15A at the raised position from the transfer arm or the like.

The lift unit 15 in which the wafer W is transferred to the holding portion 15A moves down and places the wafer W on the support base 11 as illustrated in FIG. 2, and then moves to the lowered position and waits.

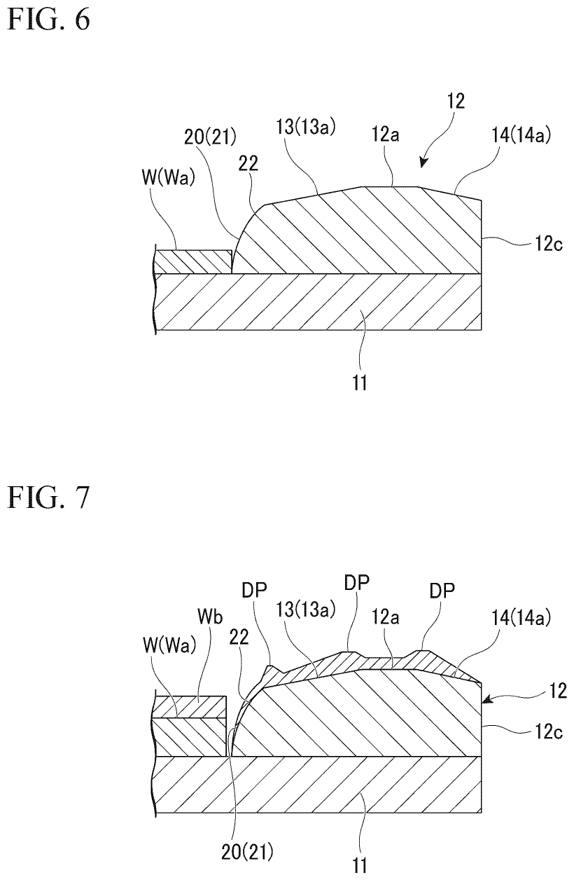

On the other hand, if a misalignment occurs when the wafer W is supported by the holding portion 15A of the lift unit 15, for example, as illustrated in FIG. 5, an edge part of the wafer W may ride onto the first inclined region 21 of the second chamfered portion 20. The wafer W that has ridden onto the first inclined region 21 slides down the curved surface 22 as indicated by the white arrow in FIG. 5. As a result, the wafer W is transferred to the support surface 11A of the support base 11, as illustrated in FIG. 6, without remaining in a state of riding on the wafer guide portion 12.

In the SiC epitaxial growth apparatus 1 in which the wafer W is transferred to the support surface 11A, the gas containing the source gas G introduced into the film formation space K of the reactor 3 and heated to a high temperature (for example, 1500 to 1650° C.) by the upper heater 4 and the lower heater 5 flows radially outward from a center of the wafer W along the first surface Wa as illustrated by the broken line in FIG. 2.

FIG. 7 is a partial cross-sectional view illustrating the wafer support device 10 after the SiC epitaxial growth processing. When supply of the gas containing the source gas G is maintained for a certain period of time while the wafer W is rotated via the support base 11, an SiC epitaxial film Wb is formed on the first surface Wa of the wafer W as illustrated in FIG. 7. Also, a deposit DP, which is a reaction product, is accumulated on the wafer guide portion 12.

In the process of supplying a raw material for the film formation and forming a film on the wafer W, the raw material that reaches the wafer guide portion 12 moves and aggregates due to a migration effect, and thereby the deposit DP is accumulated. At this time, if there is an inflection point in the wafer guide portion 12, it is considered that movement of the raw material slows down and the raw material is trapped, resulting in an increase in thickness. Therefore, in the wafer guide portion 12 having the first chamfered portion 13, the second chamfered portion 20, and the outer chamfered portion 14, the deposit DP at a portion in which the upper surface 12a and the first inclined surface 13a intersect, the deposit DP at a portion in which the upper surface 12a and the inclined surface 14a intersect, and the deposit DP at a portion in which the first inclined surface 13a and the first inclined region 21 intersect, which serve as the inflection points, grow and accumulate to their maximum thicknesses.

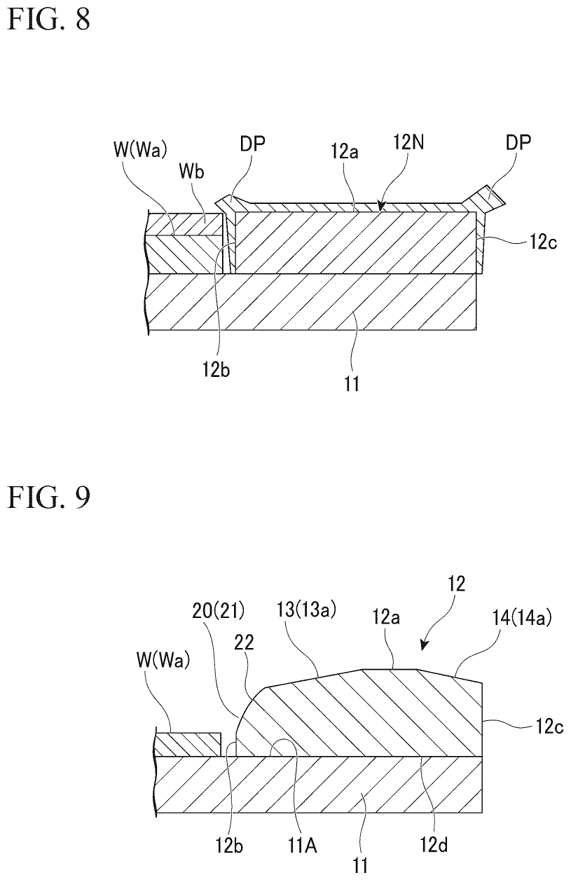

FIG. 8 is a partial cross-sectional view illustrating the wafer support device 10 after the SiC epitaxial growth processing when a wafer guide portion 12N that does not include the first chamfered portion 13, the second chamfered portion 20, and the outer chamfered portion 14 is used.

As illustrated in FIG. 8, in the wafer guide portion 12N in which the first chamfered portion 13, the second chamfered portion 20, and the outer chamfered portion 14 are not provided, the deposit DP of a portion in which the upper surface 12a and an inner circumferential surface 12b intersect and the deposit DP of a portion in which the upper surface 12a and the outer circumferential surface 12c intersect, which serve as the inflection points, grow and accumulate to their maximum thicknesses. The deposit DP in the wafer guide portion 12N protrudes to the central axis J side from the inner circumferential surface 12b and protrudes radially outward from the outer circumferential surface 12c. Also, even if slight chamfering with a chamfer amount of about 0.1 to 0.2 mm is applied, the chamfer amount is insufficient, and the deposit DP protrudes in the radial direction.

In this case, when the wafer W is raised using the lift unit 15 to remove the wafer W from the wafer support device 10, the deposit DP protruding to the central axis J side may come into contact with an end part of the wafer W. Also, the deposit DP protruding radially outward from the outer circumferential surface 12c may come into contact with other members of the partition cylinder 7, resulting in scattering and particle generation, thereby becoming a cause of particles. Since the wafer guide portion 12N is expensive, if the accumulation of the deposit DP becomes large, regeneration of the wafer guide portion 12 is performed by removing the deposit DP by grinding the inner circumferential surface 12b and the outer circumferential surface 12c through, for example, a polishing processing or grinding processing.

At this time, since the portion in which the upper surface 12a and the inner circumferential surface 12b intersect and the portion in which the upper surface 12a and the outer circumferential surface 12c intersect, which are the inflection points, are both at a right angle and have an edge shape, there is a possibility that a problem such as cracks may occur in the wafer guide portion 12N.

In contrast, in the wafer guide portion 12 of the wafer support device 10 of the embodiment, since the first chamfered portion 13, the second chamfered portion 20, and the outer chamfered portion 14 are provided, an intersection angle between the upper surface 12a and the first inclined surface 13a, an intersection angle between the upper surface 12a and the inclined surface 14a, an intersection angle between the inclined surface 14a and the outer circumferential surface 12c, and an intersection angle between the first inclined surface 13a and the first inclined region 21 are all obtuse angles. Therefore, compared to the wafer guide portion 12N in which the intersection portions serving as inflection points are right angles and prone to stress concentration, the wafer guide portion 12 has the intersection portions serving as inflection points at obtuse angles, which alleviates stress concentration and suppresses occurrence of cracks in the wafer guide portion 12. The wafer guide portion 12 in the wafer support device 10 of the embodiment can be regenerated while suppressing occurrence of cracks in both the first inclined region 21 and the outer circumferential surface 12c.

Since the inclination angle θ2 of the first inclined region 21 is larger than the inclination angle θ1 of the first inclined surface 13a of the first chamfered portion 13, the wafer W that has ridden onto the first inclined region 21 can be smoothly guided to the support surface 11A. That is, since the first inclined region 21 has a radial inward component of a normal force on the wafer W larger than that of the first inclined surface 13a, the wafer W that has ridden onto the first inclined region 21 can be guided more smoothly to the support surface 11A.

The inclination angle θ2 of the first inclined region 21 is preferably 45 degrees or more. If the inclination angle θ2 is less than 45 degrees, there is a possibility that the radial inward component of the normal force on the wafer W, that has ridden onto the first inclined region 21, may be insufficient, and the wafer W cannot be smoothly guided onto the support surface 11A.

The inclination angle θ1 of the first inclined surface 13a is preferably 10 degrees or more and less than 45 degrees. If the inclination angle θ1 is less than 10 degrees, an intersection angle between the first inclined region 21 and the first inclined surface 13a approaches a right-angled edge shape, which may cause occurrence of cracks in the wafer guide portion 12 during the regeneration processing of the first inclined region 21. Also, the deposit DP is likely to protrude to the central axis J side beyond the first inclined region 21, and there is a possibility that an end part of the wafer W may come into contact with the deposit DP during transfer, resulting in transfer defects.

If the inclination angle θ1 is 45 degrees or more, the first inclined surface 13a may act as a barrier and hinder a flow of the source gas G outward in the radial direction along the first surface Wa of the wafer W, and thereby there is a possibility that turbulence is generated. In this case, as described above, there is a possibility that an in-plane distribution of a thickness of the SiC epitaxial film Wb may not be uniform.

Therefore, when the inclination angle θ1 is set to 10 degrees or more and less than 45 degrees, it is possible to suppress cracks of the wafer guide portion 12 during regeneration processing, transfer defects of the wafer W, and generation of particles, and prevent the in-plane distribution of the thickness of the SiC epitaxial film Wb from not being uniform.

Similarly, an inclination angle of the inclined surface 14a of the outer chamfered portion 14 with respect to the support surface 11A is preferably 10 degrees or more and less than 45 degrees. If the inclination angle of the inclined surface 14a is less than 10 degrees, an intersection angle between the outer circumferential surface 12c and the inclined surface 14a approaches a right-angled edge shape, which may cause occurrence of cracks in the wafer guide portion 12 during the regeneration processing of the outer circumferential surface 12c. Also, the deposit DP is likely to protrude radially outward from the outer circumferential surface 12c and may come into contact with other members of the partition cylinder 7, resulting in scattering and particle generation, thereby becoming a cause of particles. If the inclination angle of the inclined surface 14a is 45 degrees or more, the source gas G flows radially outward from the upper surface 12a, and thereby a region between an extension of the upper surface 12a and the inclined surface 14a becomes a relatively negative pressure, making it easier for the deposits DP to occur.

According to at least one embodiment described above, the wafer guide portion 12 has the second chamfered portion 20 connected to a radially inner side of the first chamfered portion 13 and having the first inclined region 21 that extends downward at the inclination angle θ2, that is larger than the inclination angle θ1 of the first chamfered portion 13, as it approaches inward in the radial direction, and thereby the wafer W can be smoothly positioned on the support surface 11A, and damage to the wafer guide portion 12 during regeneration can be suppressed.

Also, according to at least one embodiment, since an inner end part of the second chamfered portion 20 in the radial direction intersects the lower surface 12d of the wafer guide portion 12, the inclination angle θ2 increases continuously from an upper end part to a lower end part of the second chamfered portion 20, and thus the wafer W can be more smoothly positioned on the support surface 11A.

Also, according to at least one embodiment, when the inclination angle θ1 is set to less than 45 degrees and the inclination angle θ2 is set to 45 degrees or more, it is possible to suppress cracks of the wafer guide portion 12 during regeneration processing, transfer defects of the wafer W, and generation of particles, and prevent the in-plane distribution of the thickness of the SiC epitaxial film Wb from not being uniform. Also, the wafer W that has ridden onto the first inclined region 21 can be guided more smoothly onto the support surface 11A.

Also, according to at least one embodiment, when a connection portion between the first inclined surface 13a and the first inclined region 21 is positioned above a position of the first surface Wa, protrusion of the wafer W from the wafer guide portion 12 can be suppressed.

### [Second Embodiment of Wafer Guide Portion 12]

Next, a second embodiment of the wafer guide portion 12 will be described with reference to FIG. 9.

In this figure, components the same as those in the first embodiment illustrated in FIGS. 1 to 8 will be denoted by the same reference signs, and description thereof will be omitted.

FIG. 9 is a partial enlarged view illustrating a wafer support device 10 of the second embodiment.

As illustrated in FIG. 9, the wafer guide portion 12 has an inner circumferential surface 12b extending upward along the central axis J from a lower surface 12d. A first inclined region 21 of a second chamfered portion 20 has an inner end part in the radial direction that intersects the inner circumferential surface 12b.

The other configurations are similar to those of the first embodiment.

According to at least one embodiment, in addition to obtaining the same operation and effect as those in the first embodiment, since the inner circumferential surface 12b extends upward, protrusion of the wafer W from the wafer guide portion 12 can be further suppressed.

### [Third Embodiment of Wafer Guide Portion 12]

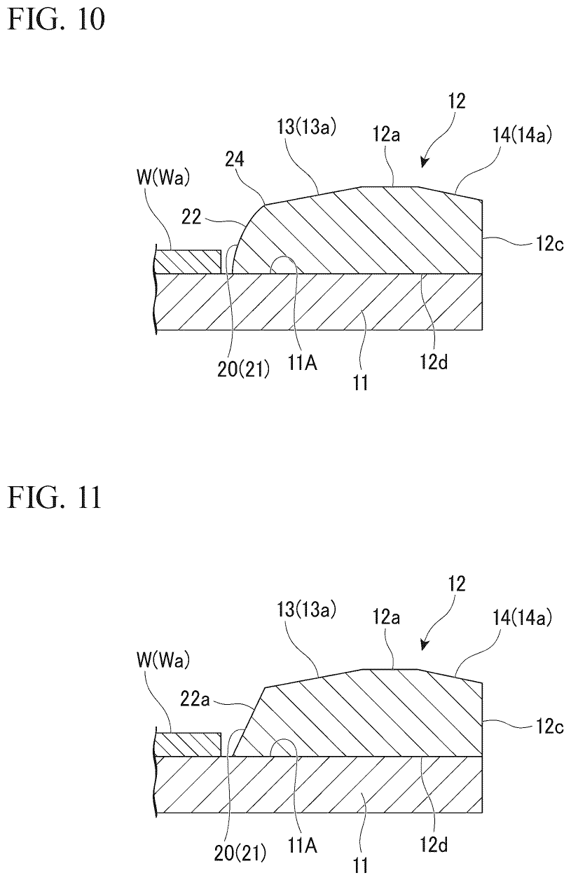

Next, a third embodiment of the wafer guide portion 12 will be described with reference to FIG. 10.

In this figure, components the same as those in the first embodiment illustrated in FIGS. 1 to 8 will be denoted by the same reference signs, and description thereof will be omitted.

FIG. 10 is a partial enlarged view illustrating a wafer support device 10 of the third embodiment.

As illustrated in FIG. 10, a second chamfered portion 20 of the wafer guide portion 12 has a second inclined region 24. The second inclined region 24 has a curved shape that is in contact with a first inclined region 21 and a first chamfered portion 13. The second inclined region 24 has an arcuate shape with an r-chamfering.

The other configurations are similar to those in the first embodiment described above.

According to at least one embodiment, since the second inclined region 24 has an arcuate shape that is in contact with the first inclined region 21 and the first chamfered portion 13, there is no protrusion formed at a portion in which the second inclined region 24 intersects the first inclined region 21, and a portion in which the second inclined region 24 intersects the first chamfered portion 13.

Therefore, according to at least one embodiment, in addition to obtaining the same operation and effect as those in the first embodiment, deposits growing thick and accumulating in the first inclined region 21 and the first chamfered portion 13 can be suppressed.

### [Fourth Embodiment of Wafer Guide Portion 12]

Next, a fourth embodiment of the wafer guide portion 12 will be described with reference to FIG. 11.

In this figure, components the same as those in the first embodiment illustrated in FIGS. 1 to 8 will be denoted by the same reference signs, and description thereof will be omitted.

FIG. 11 is a partial enlarged view illustrating a wafer support device 10 of the fourth embodiment.

As illustrated in FIG. 11, a first inclined region 21 in the wafer guide portion 12 has a second inclined surface 22a that is linearly inclined in a direction toward a lower side as it approaches inward in the radial direction.

The other configurations are similar to those in the first embodiment described above.

According to at least one embodiment, the same operation and effect as those of the first embodiment can be obtained.

Further, a first chamfered portion 13 may be an r-chamfer that extends and inclines to be curved in an arc shape in a direction toward a lower side as it approaches inward in the radial direction from an upper surface 12a. An outer chamfered portion 14 may be an r-chamfer that extends and inclines to be curved in an arc shape in a direction toward a lower side as it approaches outward in the radial direction from the upper surface 12a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wafer support device comprising:
a support base having a support surface which supports a wafer and configured to rotate with a central axis extending in a normal direction of the support surface as a center; and
an annular wafer guide portion surrounding a circumference of the wafer supported on the support surface with the central axis as a center, wherein
the wafer guide portion includes:
a first chamfered portion inclined downward going radially inward from an upper surface with the central axis as a center; and
a second chamfered portion having a first inclined region facing downward at an inclination angle larger than an inclination angle of the first chamfered portion with respect to the support surface going radially inward, and connected to an inner side of the first chamfered portion in the radial direction.

2. The wafer support device according to claim 1, wherein the second chamfered portion has a curved second inclined region which is in contact with the first inclined region and the first chamfered portion in a cross section including the central axis.

3. The wafer support device according to claim 1, wherein an inner end part of the second chamfered portion in the radial direction intersects a lower surface of the wafer guide portion.

4. The wafer support device according to claim 1, wherein
the wafer guide portion has an inner circumferential surface extending upward along the central axis from a lower surface, and
an inner end part of the second chamfered portion in the radial direction intersects the inner circumferential surface.

5. The wafer support device according to claim 1, wherein
an inclination angle of the first chamfered portion with respect to the support surface is less than 45 degrees, and
an inclination angle of the first inclined region with respect to the support surface is 45 degrees or more.

6. The wafer support device according to claim 1, wherein the first chamfered portion has a first inclined surface which is linearly inclined in a direction toward a lower side as it approaches inward in the radial direction in a cross section including the central axis.

7. The wafer support device according to claim 1, wherein the first inclined region has a second inclined surface which is linearly inclined in a direction toward a lower side as it approaches inward in the radial direction in a cross section including the central axis.

8. The wafer support device according to claim 1, wherein the first inclined region has a curved surface which is inclined in a curved manner in a direction toward a lower side as it approaches inward in the radial direction in a cross section including the central axis.

9. The wafer support device according to claim 1, wherein at least a surface of the wafer guide portion is formed of poly-SiC.

10. An SiC epitaxial growth apparatus comprising a wafer support device, wherein
the wafer support device includes:
a support base having a support surface which supports a wafer and rotating with a central axis extending in a normal direction of the support surface as a center; and
an annular wafer guide portion surrounding a circumference of the wafer supported on the support surface with the central axis as a center, in which
the wafer guide portion includes:
a first chamfered portion inclined downward going radially inward from an upper surface with the central axis as a center; and
a second chamfered portion having a first inclined region facing downward at an inclination angle larger than an inclination angle of the first chamfered portion with respect to the support surface going radially inward, and connected to an inner side of the first chamfered portion in the radial direction.
